(19) United States
(12) Patent Application Publication
(10) Pub. No.: US 2002/0053678 A1
(43) Pub. Date: May 9, 2002

(54) Semiconductor integrated circuit

(75) Inventors: Kazuhiro Shiba, Tokyo (JP); Kenichi Kobayashi, Tokyo (JP)

Correspondence Address: SUGHRUE, MION, ZINN, MACPEAK & SEAS, 2100 Pennsylvania Avenue, N.W., Washington, DC, 20037-3202, US

(73) Assignee: NEC CORPORATION

(21) Appl. No.: 09/971,713

(22) Filed: Oct. 9, 2001

(30) Foreign Application Priority Data
Oct. 10, 2000 (JP) 2000-309383

(51) Int. Cl. H01L 33/00; G02F 1/295

(52) U.S. Cl. 257/98; 385/9; 385/10

(57) ABSTRACT

A semiconductor integrated circuit which has a wavelength converting function and a wavelength demultiplexing function is made up of a relatively small number of parts, allows parts to be integrated easily, and can be manufactured at a relatively low cost. The semiconductor integrated circuit includes an MMI waveguide for converting an optical signal having a second wavelength into an optical signal having a first wavelength, a first input port mounted on an entrance end of the MMI waveguide, for being supplied with the optical signal having the first wavelength, a second input port for being supplied with the optical signal having the second wavelength, and at least one output port mounted on an exit end of the MMI waveguide, for extracting the optical signal having the first wavelength. The MMI waveguide has a refractive index variable depending on the intensity of the optical signal having the second wavelength.

### BACKGROUND OF THE INVENTION

1. Field of the Invention

The present invention relates to a semiconductor integrated circuit, and more particularly to a semiconductor integrated circuit having a wavelength converting function, which is important in optical communications, for converting an optical signal having a certain wavelength into an optical signal having a different wavelength.

2. Description of the Related Art

FIG. 1 of the accompanying drawings is a block diagram of a conventional wavelength converter for converting an optical signal having wavelength λ1 into an optical signal having wavelength λ2.

As shown in FIG. 1, the conventional wavelength converter comprises photodetector 702, semiconductor laser (LD) driver circuit 703, and semiconductor laser (LD) 704.

Optical input signal 701 having wavelength λ1 is applied to photodetector 702, which outputs an inputted state of optical input signal 701 to LD driver circuit 703. LD driver circuit 703 energizes LD 704 having oscillation wavelength λ2 depending on an output signal from photodetector 702. LD 704 produces optical output signal 705 having wavelength λ2 depending on the inputted state of optical input signal 701 having wavelength λ1.

One semiconductor integrated circuit for performing a demultiplexing function is disclosed as an optical waveguide circuit in Japanese patent laid-open publication No. 8-201648.

The optical waveguide circuit disclosed in the above publication uses multimode interference (MMI) optical waveguides, and comprises a light entering unit for converting spot sizes, an MMI demultiplexer, an optical waveguide for emitting light having a wavelength of 1.3 μm, a photodetector for detecting light having a wavelength of 1.3 μm, a semiconductor laser, an optical waveguide for emitting light having a wavelength of 1.55 μm, and a photodetector for detecting light having a wavelength of 1.55 μm, the components being integrated. The length of the MMI demultiplexer is set to provide either a self-imaging state for focusing the light having the wavelength of 1.3 μm and the light having the wavelength of 1.55 μm in a field which is the same as the field of the incident light or a 3 dB coupler state for dividing these lights into two images.

The conventional wavelength converter shown in FIG. 1 is made up of a number of parts including the photodetector, the LD driver circuit, and the LD, which are difficult to integrate into a unitary assembly.

Since optical axis alignment is needed in assembling the parts, the assembling process is complex, presenting an obstacle to efforts to make the conventional wavelength converter less costly.

### SUMMARY OF THE INVENTION

It is therefore an object of the present invention to provide a semiconductor integrated circuit having a wavelength converting function and a wavelength demultiplexing function, which is made up of a relatively small number of parts, allows parts to be integrated easily, and can be manufactured at a relatively low cost.

According to an aspect of the present invention, there is provided a semiconductor integrated circuit comprising an MMI waveguide for converting an optical signal having a second wavelength into an optical signal having a first wavelength, a first input port mounted on an entrance end of the MMI waveguide, for being supplied with the optical signal having the first wavelength, a second input port for being supplied with the optical signal having the second wavelength, and at least one output port mounted on an exit end of the MMI waveguide, for extracting the optical signal having the first wavelength, the MMI waveguide having a refractive index variable depending on the intensity of the optical signal having the second wavelength.

The refractive index of the MMI waveguide may vary according to an optical nonlinear refractive index effect due to the optical signal from the first input port for varying an interference pattern of the optical signal from the second input port.

The second input port may be mounted on either the entrance end or the exit end of the MMI waveguide.

The semiconductor integrated circuit may further comprise a semiconductor laser connected to the first input port, for outputting the optical signal having the first wavelength.

The semiconductor laser may have an active layer having a multi-quantum well structure.

The semiconductor laser may comprise a distributed-feedback diffraction grating and a phase shifting region disposed in the distributed-feedback diffraction grating, for shifting a phase by at most λ/4.

According to another aspect of the present invention, there is provided a semiconductor integrated circuit comprising an MMI waveguide for effecting a multimode interference on an inputted optical signal having a second wavelength to output an interference light having the second wavelength from at least one output port, the MMI waveguide having a refractive index variable due to an inputted optical signal having a first wavelength to change a position where the interference light having the second wavelength is coupled to the output port.

The MMI waveguide may change the strength with which the interference light having the second wavelength is coupled to the output port, in response to the optical signal having the first wavelength which is applied to the MMI waveguide.

The above and other objects, features, and advantages of the present invention will become apparent from the following description with reference to the accompanying drawings, which illustrate an example of the present invention.

### BRIEF DESCRIPTION OF THE DRAWINGS

FIG. 1 is a block diagram of a conventional wavelength converter;

FIG. 2(a) is a plan view of a semiconductor integrated circuit according to the present invention, showing an interference pattern of light emitted from an LD when an optical input signal is on;

FIG. 2(b) is a plan view of the semiconductor integrated circuit according to the present invention, showing an interference pattern of light emitted from the LD when an optical input signal is off;

FIG. 3 is a cross-sectional view of the semiconductor integrated circuit in a first fabrication step, taken across a central portion of the resonator of a semiconductor laser, in the direction in which a laser beam is emitted therefrom;

FIG. 4(a1 ) is a cross-sectional view of the semiconductor integrated circuit in a second fabrication step, taken across the central portion of the resonator of the semiconductor laser, in the direction in which the laser beam is emitted therefrom;

FIG. 4(a2) is a plan view of the semiconductor integrated circuit in the second fabrication step;

FIG. 4(b1) is a cross-sectional view of the semiconductor integrated circuit in a third fabrication step, taken across the central portion of the resonator of the semiconductor laser, in the direction in which the laser beam is emitted therefrom;

FIG. 4(b2) is a plan view of the semiconductor integrated circuit in the third fabrication step;

FIG. 5(c1) is a cross-sectional view of the semiconductor integrated circuit in a fourth fabrication step, taken across the central portion of the resonator of the semiconductor laser, in the direction in which the laser beam is emitted therefrom FIG. 5(c2) is a plan view of the semiconductor integrated circuit in the fourth fabrication step;

FIG. 5(d1) is a cross-sectional view of the semiconductor integrated circuit in a fifth fabrication step, taken across the central portion of the resonator of the semiconductor laser, in the direction in which the laser beam is emitted therefrom;

FIG. 5(d1) is a plan view of the semiconductor integrated circuit in the fifth fabrication step;

FIG. 6(e1) is a cross-sectional view of the semiconductor integrated circuit in a sixth fabrication step for forming a mask, taken across the central portion of the resonator of the semiconductor laser, in the direction in which the laser beam is emitted therefrom;

FIG. 6(e2) is a plan view of the semiconductor integrated circuit in the sixth fabrication step for forming a mask;

FIG. 6(f1) is a cross-sectional view of the semiconductor integrated circuit after it is shaped in the sixth fabrication step, taken across the central portion of the resonator of the semiconductor laser, in the direction in which the laser beam is emitted therefrom;

FIG. 6(f2) is a plan view of the semiconductor integrated circuit after it is shaped in the sixth fabrication step;

FIG. 7(g1) is a cross-sectional view of the semiconductor integrated circuit in a seventh fabrication step, taken across the central portion of the resonator of the semiconductor laser, in the direction in which the laser beam is emitted therefrom;

FIG. 7(g2) is a plan view of the semiconductor integrated circuit in the seventh fabrication step;

FIGS. 7(g3) through 7(g5) are cross-sectional views taken along lines 7(g3)-7(g3), 7(g4)-7(g4), 7(g5)-7(g5), respectively, of FIG. 7(g2);

FIG. 7(h) is a cross-sectional view of the semiconductor integrated circuit after it is shaped in the seventh fabrication step, taken across the central portion of the resonator of the semiconductor laser, in the direction in which the laser beam is emitted therefrom; and

FIG. 8 is a diagram showing a plurality of interference patterns which can be provided an MMI waveguide depending on its dimensions.

### DETAILED DESCRIPTION OF THE PREFERRED EMBODIMENTS

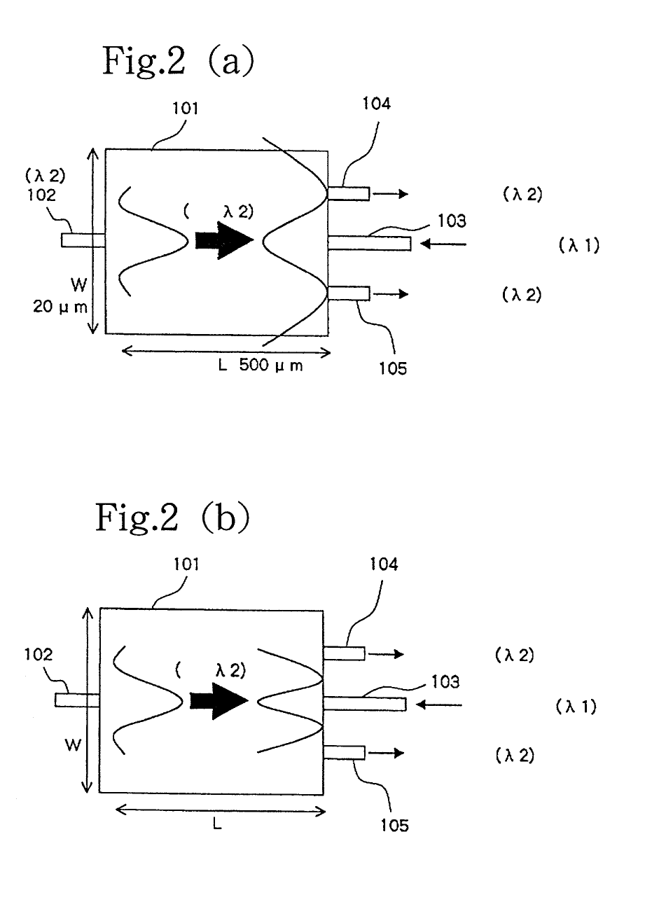

FIGS. 2(a) and 2(b) show in plan a semiconductor integrated circuit according to the present invention.

As shown in FIGS. 2(a) and 2(b), the semiconductor integrated circuit has MMI waveguide 101, LD 102 connected to an entrance end of MMI waveguide 101, for emitting light having wavelength λ2, input port 103 connected to an exit end of MMI waveguide 101 opposite to the entrance end, for being supplied with an optical input signal having wavelength λ1 which is to be converted, and output ports 104, 105 connected to the exit end, for extracting the light having the wavelength λ2 which is emitted from LD 102.

The light emitted from LD 102 and propagated through MMI waveguide 101 is subject to an interference whose interference pattern varies depending on the position in which the light is propagated. The refractive index of MMI waveguide 101 varies depending on an inputted state of an optical input signal having wavelength λ1 which is applied to input port 103. The interference pattern of the light emitted from LD 102 and propagated through MMI waveguide 101 also varies depending on the refractive index of MMI waveguide 101.

The refractive index of MMI waveguide 101 varies depending on the light having wavelength λ1 due to an optical nonlinear refractive index effect. Specifically, the refractive index varies due to a polarization P that is induced in the semiconductor (substance) of MMI waveguide 101 by the applied light having wavelength λ1.

FIG. 2(a) shows an interference pattern of light emitted from LD 102 when the optical input signal is on, and FIG. 2(b) shows an interference pattern of light emitted from LD 102 when the optical input signal is off. When the optical input signal is on, the light emitted from LD 102 is of such an interference pattern which is strongly coupled to output ports 104, 105. When the optical input signal is off, the refractive index of MMI waveguide 101 varies for the light emitted from LD 102 to be of such an interference pattern which is not strongly coupled to output ports 104, 105.

The semiconductor integrated circuit constructed as described above operates as follows: Output ports 104, 105 output optical output signals having wavelength λ2 depending on the optical input signal having wavelength λ1 which is applied to input port 103. The semiconductor integrated circuit simultaneously converts wavelength λ1 of the optical input signal into wavelength λ2 of the optical output signals, and demultiplexes the optical input signal into the optical output signals.

MMI waveguide 101 has a core and a cladding. If the core of MMI waveguide 101 has a refractive index of 3.543 and the cladding thereof has a refractive index of 3.511, and wavelength λ2 from LD 102 is 1.55 μm, then MMI waveguide 101 has a width W of 20 μm and a length L of 691 μm. These numerical values are given by way of example only, and the width and length of MMI waveguide 101 may be of suitable dimensions depending on the refractive index of the core, the refractive index of the cladding, and the wavelength from LD 102. MMI waveguide 101 is made of such a material that it is transparent to wavelength λ2 and its refractive index varies due to wavelength λ1.

LD 102 comprises a phase-shift DFB (distributed feedback) laser, which has a structure and characteristics as described below, as disclosed in Japanese patent laid-open publication No. 2000-077774. The phase-shift DFB laser is continuously oscillatable for continuous wavelength conversion.

The phase-shift DFB laser includes a resonator having a diffraction grating structure which is divided into a plurality of regions in the longitudinal direction of the resonator, with a phase shifter disposed between the regions. The phase shifter shifts the phase by a quantity represented by λ/n (where λindicates an oscillation wavelength and n>4).

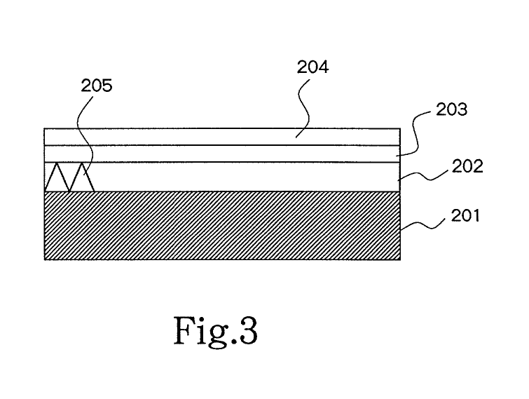

A process of fabricating the semiconductor integrated circuit according to the present invention will be described below with reference to FIGS. 3 through 7(h) which show successive steps of the process.

FIG. 3 shows in cross section the semiconductor integrated circuit in a first fabrication step, taken across a central portion of the resonator of a semiconductor laser, in the direction in which a laser beam is emitted therefrom.

In the first fabrication step, a semiconductor laser is formed. As shown in FIG. 3, light guide layer 202 of InGaAsP, MQW (Multi-Quantum Well) active layer 203 of InGaAsP, and cap layer 204 of InP are successively deposited on InP substrate 201.

MQW active layer 203 is made of two types of InGaAsP alternately deposited to provide an inter-quantum-well level wavelength of 1.55 μm.

A resonator comprises diffraction gratings 205 disposed in respective two regions in light guide layer 202 in the longitudinal direction of the resonator, with a phase shifting region positioned between diffraction gratings 205. The phase shifting region shifts the phase by a quantity represented by λ/n (where λ indicates an oscillation wavelength and n>4), e.g., λ/8 (n=8).

In the present embodiment, the resonator has a length L and each diffraction grating has a period (pitch) Λ. The phase shifting region comprises a flat surface having a width λ/n in the longitudinal direction of the resonator. As a result, peaks of diffraction gratings 205 which are immediately close to the phase shifting region are spaced from each other by a distance of (Λ−λ/n).

The phase shifting region may not necessarily be a flat surface, but diffraction gratings 205 may be disposed adjacent to each other to provide a phase difference of λ/n therebetween.

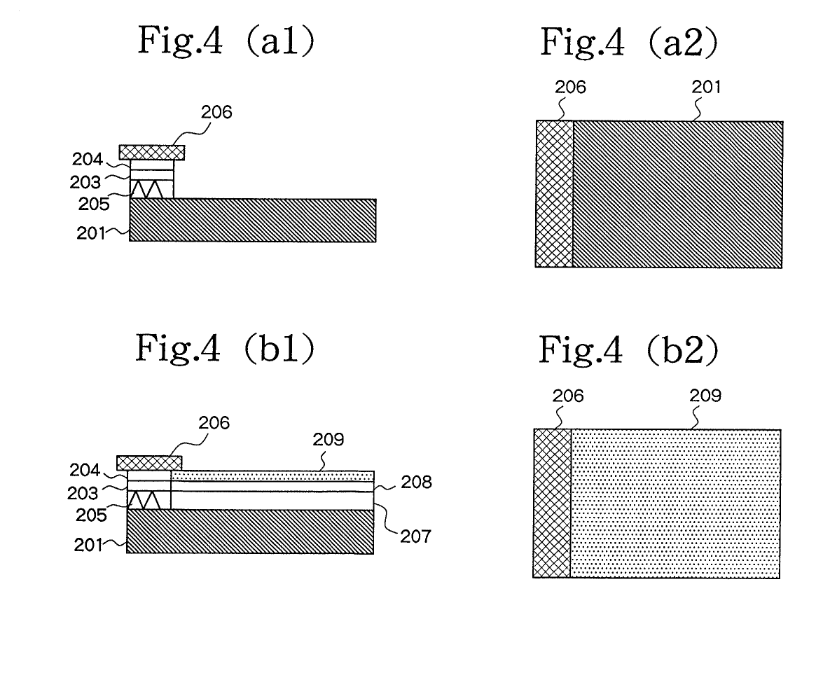

FIG. 4(a1 ) shows in cross section the semiconductor integrated circuit in a second fabrication step, taken across the central portion of the resonator of the semiconductor laser, in the direction in which the laser beam is emitted therefrom, and FIG. 4(a2) shows in plan the semiconductor integrated circuit in the second fabrication step.

In the second fabrication step, portions other than a semiconductor laser region are removed. As shown in FIGS. 4(a1) and 4(a2), SiO₂ mask 206 is partly formed over the semiconductor laser region, and portions other than the region covered with SiO₂ mask 206 are removed until substrate 201 is exposed.

FIG. 4(b1) shows in cross section the semiconductor integrated circuit in a third fabrication step, taken across the central portion of the resonator of the semiconductor laser, in the direction in which the laser beam is emitted therefrom, and FIG. 4(b2) shows in plan the semiconductor integrated circuit in the third fabrication step.

In the third fabrication step, an MMI waveguide region is formed. Thin film core 207 of n-InGaAsP, common core 208 of n-InGaAsP, and cladding layer 209 of p-InP are successively deposited on substrate 201 which has been exposed in the second fabrication step.

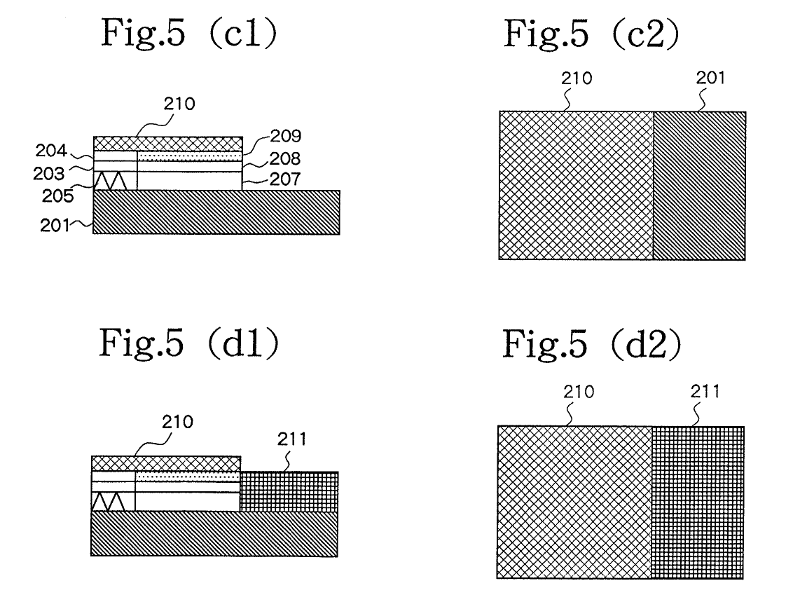

FIG. 5(c1) shows in cross section the semiconductor integrated circuit in a fourth fabrication step, taken across the central portion of the resonator of the semiconductor laser, in the direction in which the laser beam is emitted therefrom, and FIG. 5(c2) shows in plan the semiconductor integrated circuit in the fourth fabrication step.

In the fourth fabrication step, portions other than the semiconductor laser region and the MMI waveguide region are removed. As shown in FIGS. 5(c1) and 5(c2), SiO₂ mask 210 is partly formed over the semiconductor laser region and the MMI waveguide region, and portions ductor laser region and the MMI waveguide region, and portions other than the regions covered with SiO₂ mask 210 are removed until substrate 201 is exposed.

FIG. 5(d1) shows in cross section the semiconductor integrated circuit in a fifth fabrication step, taken across the central portion of the resonator of the semiconductor laser, in the direction in which the laser beam is emitted therefrom, and FIG. 5(d2) shows in plan the semiconductor integrated circuit in the fifth fabrication step.

In the fifth fabrication step, an input port region and an output port region are formed. Light guide layer 211 of InGaAsP is deposited on substrate 201 which has been exposed in the second fabrication step.

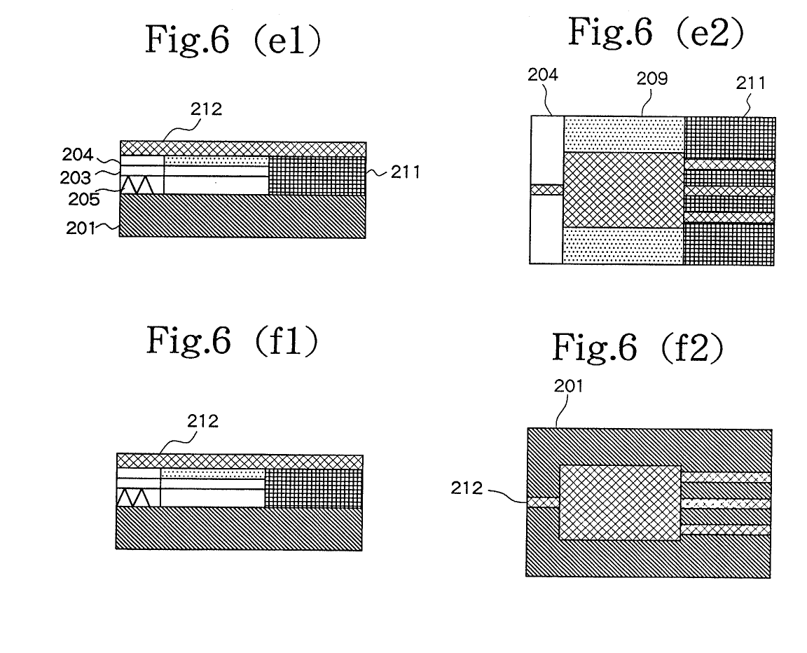

FIGS. 6(e1) and 6(e2) are illustrative of a sixth fabrication step for shaping the semiconductor laser region, the MMI waveguide region, the input port region, and the output port region. FIG. 6(e1) shows in cross section the semiconductor integrated circuit in the sixth fabrication step for forming a mask, taken across the central portion of the resonator of the semiconductor laser, in the direction in which the laser beam is emitted therefrom, and FIG. 6(e2) shows in plan the semiconductor integrated circuit in the sixth fabrication step for forming a mask. FIG. 6(f1) shows in cross section the semiconductor integrated circuit after it is shaped in the sixth fabrication step, taken across the central portion of the resonator of the semiconductor laser, in the direction in which the laser beam is emitted therefrom, and FIG. 6(f2) shows in plan the semiconductor integrated circuit after it is shaped in the sixth fabrication step.

As shown in FIG. 6(e2), SiO₂ mask 212 is formed over the semiconductor laser region, the MMI waveguide region, the input port region, and the output port region in a pattern to shape them as shown in FIGS. 2(a) and 2(b). Thereafter, as shown in FIG. 6(f2), portions other than the regions covered with mask 212 are removed until substrate 201 is exposed.

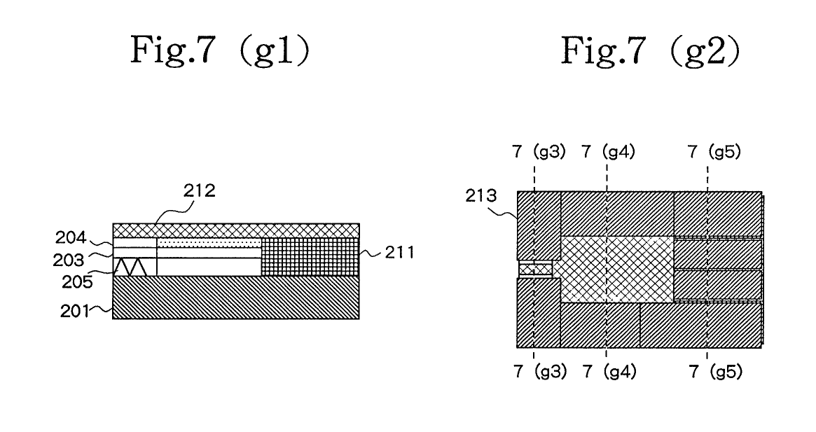

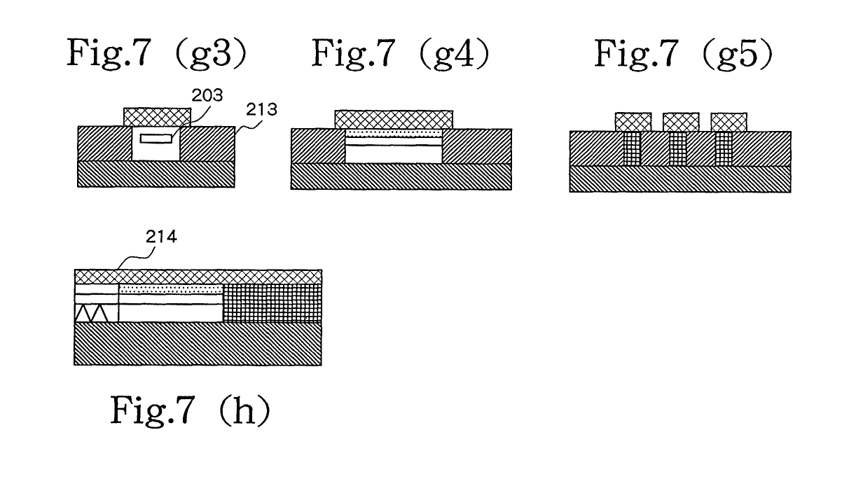

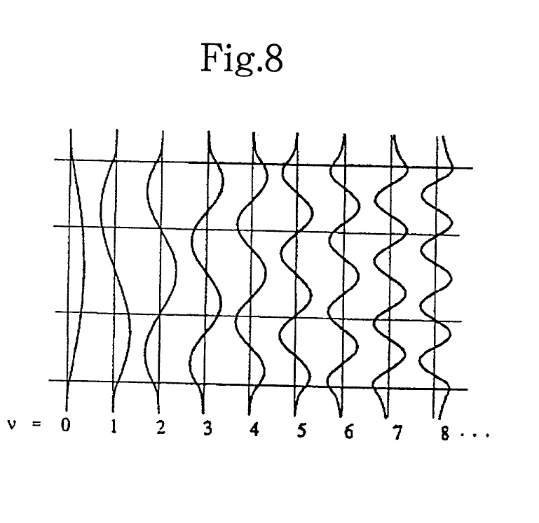

FIG. 7(g1) shows in cross section the semiconductor integrated circuit in a seventh fabrication step, taken across the central portion of the resonator of the semiconductor laser, in the direction in which the laser beam is emitted therefrom, and FIG. 7(g2) shows in plan the semiconductor integrated circuit in the seventh fabrication step. FIGS. 7(g3) through 7(g5) are cross-sectional views taken along lines 7(g3)-7(g3), 7(g4 )-7(g4 ), 7(g5)-7(g5), respectively, of FIG. 7(g2). FIG. 7(h) shows in cross section the semiconductor integrated circuit after it is shaped in the seventh fabrication step, taken across the central portion of the resonator of the semiconductor laser, in the direction in which the laser beam is emitted therefrom.

As shown in FIGS. 7(g2) through 7(g5), embedding layer 213 of Fe-doped InP is formed on substrate 201 which has been exposed in the sixth fabrication step. Thereafter, as shown in FIG. 7(h), mask 212 is removed, and embedding layer 214 of InP is formed to provide a flat surface.

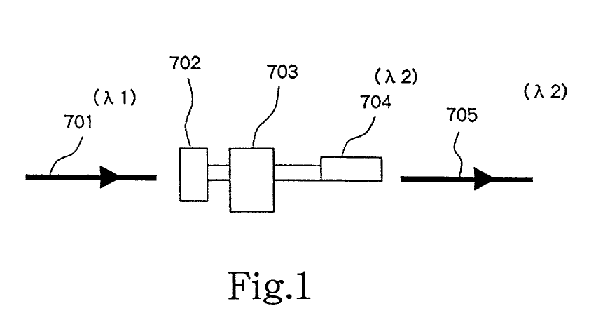

In the above embodiment, since the components can be formed altogether on the InP substrate according to the selective growth technique, the number of module fabrication steps including optical axis alignment can greatly be reduced as compared with the conventional structure shown in FIG. 1, and the semiconductor integrated circuit can be assembled with high reproducibility.

In the illustrated embodiment, MMI waveguide 101 provides an interference pattern for demultiplexing the optical input signal into two optical signals at the end of MMI waveguide 101 near output ports 104, 105 and coupling the optical signals to output ports 104, 105. However, an MMI waveguide can provide various interference patterns depending on its dimensions, as shown in FIG. 8. FIG. 8 shows interference patterns of 9 orders ranging from 0 to 8. Thus, the number of demultiplexed optical signals can be selected depending on the dimensions of the MMI waveguide. Specifically, the dimensions of an MMI waveguide may be determined to produce a desired number of demultiplexed optical signals, and output ports may be positioned at the end of the MMI waveguide where the demultiplexed optical signals can strongly be coupled to the output ports. In this manner, a demultiplexer for producing a desired number of demultiplexed optical signals can be constructed.

In the above embodiment, second input port 103 is mounted on the exit end of the MMI waveguide for the purpose of causing the refractive index of the MMI waveguide to vary, due to the optical input signal having wavelength λ1 that is applied to second input port 103, uniformly in the direction in which the optical output signal having wavelength λ2 that is emitted from semiconductor laser 102 is propagated. To achieve the above purpose, second input port 103 may be mounted on the entrance end of the MMI waveguide as well as the exit end of the MMI waveguide. Second input port 103 is not limited to any particular position insofar as the refractive index of the MMI waveguide varies substantially uniformly in the direction in which the optical output signal having wavelength λ2 that is emitted from the semiconductor laser is propagated.

The semiconductor integrated circuit according to the present invention, which serves to convert and demultiplex a wavelength, is made up of a relatively small number of parts, allows parts to be integrated easily, and can be manufactured at a relatively low cost.

While a preferred embodiment of the present invention has been described using specific terms, such description is for illustrative purposes only, and it is to be understood that changes and variations may be made without departing from the spirit or scope of the following claims.

What is claimed is:

1. A semiconductor integrated circuit comprising:
an MMI waveguide for converting an optical signal having a second wavelength into an optical signal having a first wavelength;
a first input port mounted on an entrance end of said MMI waveguide, for being supplied with the optical signal having the first wavelength;
a second input port for being supplied with the optical signal having the second wavelength; and
at least one output port mounted on an exit end of said MMI waveguide, for extracting the optical signal having the first wavelength;
said MMI waveguide having a refractive index variable depending on the intensity of the optical signal having the second wavelength.

2. A semiconductor integrated circuit according to claim 1, wherein the refractive index of said MMI waveguide varies according to an optical nonlinear refractive index effect due to the optical signal from said first input port for varying an interference pattern of the optical signal from said second input port.

3. A semiconductor integrated circuit according to claim 1, wherein said second input port is mounted on either the entrance end or the exit end of said MMI waveguide.

4. A semiconductor integrated circuit according to claim 2, wherein said second input port is mounted on either the entrance end or the exit end of said MMI waveguide.

5. A semiconductor integrated circuit according to claim 1, further comprising:
a semiconductor laser connected to said first input port, for outputting the optical signal having the first wavelength.

6. A semiconductor integrated circuit according to claim 2, further comprising:
a semiconductor laser connected to said first input port, for outputting the optical signal having the first wavelength.

7. A semiconductor integrated circuit according to claim 3, further comprising:
a semiconductor laser connected to said first input port, for outputting the optical signal having the first wavelength.

8. A semiconductor integrated circuit according to claim 4, further comprising:
a semiconductor laser connected to said first input port, for outputting the optical signal having the first wavelength.

9. A semiconductor integrated circuit according to claim 5, wherein said semiconductor laser has an active layer having a multi-quantum well structure.

10. A semiconductor integrated circuit according to claim 6, wherein said semiconductor laser has an active layer having a multi-quantum well structure.

11. A semiconductor integrated circuit according to claim 7, wherein said semiconductor laser has an active layer having a multi-quantum well structure.

12. A semiconductor integrated circuit according to claim 8, wherein said semiconductor laser has an active layer having a multi-quantum well structure.

13. A semiconductor integrated circuit according to claim 5, wherein said semiconductor laser comprises;
a distributed-feedback diffraction grating; and
a phase shifting region disposed in said distributed-feedback diffraction grating, for shifting a phase by at most λ/4.

14. A semiconductor integrated circuit according to claim 6, wherein said semiconductor laser comprises;
a distributed-feedback diffraction grating; and
a phase shifting region disposed in said distributed-feedback diffraction grating, for shifting a phase by at most λ/4.

15. A semiconductor integrated circuit according to claim 7, wherein said semiconductor laser comprises;
a distributed-feedback diffraction grating; and
a phase shifting region disposed in said distributed-feedback diffraction grating, for shifting a phase by at most λ/4.

16. A semiconductor integrated circuit according to claim 8, wherein said semiconductor laser comprises;
a distributed-feedback diffraction grating; and
a phase shifting region disposed in said distributed-feedback diffraction grating, for shifting a phase by at most λ/4.

17. A semiconductor integrated circuit according to claim 9, wherein said semiconductor laser comprises;
a distributed-feedback diffraction grating; and
a phase shifting region disposed in said distributed-feedback diffraction grating, for shifting a phase by at most λ/4.

18. A semiconductor integrated circuit according to claim 10, wherein said semiconductor laser comprises;
a distributed-feedback diffraction grating; and
a phase shifting region disposed in said distributed-feedback diffraction grating, for shifting a phase by at most λ/4.

19. A semiconductor integrated circuit according to claim 11, wherein said semiconductor laser comprises;
a distributed-feedback diffraction grating; and
a phase shifting region disposed in said distributed-feedback diffraction grating, for shifting a phase by at most λ4.

20. A semiconductor integrated circuit according to claim 12, wherein said semiconductor laser comprises;
a distributed-feedback diffraction grating; and
a phase shifting region disposed in said distributed-feedback diffraction grating, for shifting a phase by at most λ/4.

21. A semiconductor integrated circuit comprising:
an MMI waveguide for effecting a multimode interference on an inputted optical signal having a second wavelength to output an interference light having the second wavelength from at least one output port;
said MMI waveguide having a refractive index variable due to an inputted optical signal having a first wavelength to change a position where the interference light having the second wavelength is coupled to said output port.

22. A semiconductor integrated circuit according to claim 21, wherein said MMI waveguide changes the strength with which the interference light having the second wavelength is coupled to said output port, in response to the optical signal having the first wavelength which is applied to said MMI waveguide.
